(19) United States
(12) Patent Application Publication
(10) Pub. No.: US 2015/0373868 A1
(43) Pub. Date: Dec. 24, 2015

(54) CABINETS AND METHODS FOR REMOVING UNDESIRABLE GAS IN CABINETS

(71) Applicant: Emerson Network Power, Energy Systems, North America, Inc., Warrenville, IL (US)

(72) Inventor: Jin Harrison ELKINS, Auburn, AL (US)

(21) Appl. No.: 14/743,506

(22) Filed: Jun. 18, 2015

Related U.S. Application Data
(60) Provisional application No. 62/013,768, filed on Jun. 18, 2014.
(60) Provisional application No. 62/058,960, filed on Oct. 2, 2014.

(51) Int. Cl. H05K 7/20; F24F 7/04

(52) U.S. Cl. CPC H05K 7/20; F24F 7/04

(57) ABSTRACT

A cabinet for housing one or more components capable of releasing an undesirable gas over time includes an inlet channel for conveying air from an exterior side of the cabinet to an interior side of the cabinet, an outlet channel for conveying air and undesirable gas from the interior side of the cabinet to the exterior side of the cabinet, and a thermoelectric module (TEM) thermally coupled to the inlet channel and/or the outlet channel for promoting a temperature differential between air in the inlet channel and air in the outlet channel. The temperature differential promotes a flow of air from the interior side of the cabinet through the outlet channel to the exterior side of the cabinet to thereby remove the undesirable gas from the cabinet.

### CROSS-REFERENCE TO RELATED APPLICATIONS

This application claims the benefit of U.S. Provisional Application No. 62/013,768 filed Jun. 18, 2014 and U.S. Provisional Application No. 62/058,960 filed Oct. 2, 2014. The entire disclosure of each of the above applications is incorporated herein by reference.

### FIELD

The present disclosure relates to cabinets and methods for removing undesirable gas in cabinets.

### BACKGROUND

This section provides background information related to the present disclosure which is not necessarily prior art.

Cabinets may house components that release undesirable gases. For example, some batteries release hydrogen gas when recharging. This hydrogen gas may cause explosions when, for example, the concentration of hydrogen gas in the cabinet rises above about four percent. Typically, cabinets include perforations near a top portion of the cabinet to allow the hydrogen gas to escape as it rises.

### SUMMARY

This section provides a general summary of the disclosure, and is not a comprehensive disclosure of its full scope or all of its features.

According to one aspect of the present disclosure, a battery cabinet for housing one or more rechargeable batteries capable of releasing hydrogen gas over time is disclosed. The battery cabinet includes an inlet channel for conveying air from an exterior side of the battery cabinet to an interior side of the battery cabinet, an outlet channel for conveying air and hydrogen gas from the interior side of the battery cabinet to the exterior side of the battery cabinet, and a thermoelectric module (TEM) thermally coupled to the inlet channel and/or the outlet channel for promoting a temperature differential between air in the inlet channel and air in the outlet channel. The temperature differential promotes a flow of air from the interior side of the battery cabinet through the outlet channel to the exterior side of the battery cabinet to thereby remove hydrogen gas from the battery cabinet.

According to another aspect of the present disclosure, a cabinet for housing one or more components capable of releasing an undesirable gas over time is disclosed. The cabinet includes an inlet channel for conveying air from an exterior side of the cabinet to an interior side of the cabinet, an outlet channel for conveying air and undesirable gas from the interior side of the cabinet to the exterior side of the cabinet, and a TEM thermally coupled to the inlet channel and/or the outlet channel for promoting a temperature differential between air in the inlet channel and air in the outlet channel. The temperature differential promotes a flow of air from the interior side of the cabinet through the outlet channel to the exterior side of the cabinet to thereby remove the undesirable gas from the cabinet.

According to yet another aspect of the present disclosure, a method of promoting a flow of air from an interior side of a battery cabinet to an exterior side of the battery cabinet to thereby remove hydrogen gas from the battery cabinet is disclosed. The method includes promoting a temperature differential between air in an inlet channel and air in an outlet channel with a TEM to promote a flow of air from the interior side of the battery cabinet through the outlet channel to the exterior side of the battery cabinet to thereby remove hydrogen gas from the battery cabinet.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a block diagram of a cabinet including an inlet channel, an outlet channel, and a TEM to promote a temperature differential between air in the inlet channel and air in the outlet channel according to one example embodiment of the present disclosure.

FIG. 2 is a block diagram of a cabinet including an inlet channel and an outlet channel coupled to an inlet port and an outlet port, respectively, that are not positioned adjacent each other according to another example embodiment.

FIG. 3 is a block diagram of a cabinet including an inlet channel, an outlet channel, and a TEM having a control circuit according to yet another example embodiment.

FIG. 4 is a block diagram of a cabinet including an inlet channel, an outlet channel, a TEM, and a temperature control device according to another example embodiment.

FIG. 5 is a block diagram of a cabinet including an outlet channel and an inlet channel extending to a lower portion of the cabinet according to yet another example embodiment.

FIG. 6 is a block diagram of the cabinet of FIG. 5 including filters positioned within the inlet channel and the outlet channel.

FIG. 7 is a block diagram of a portion of a cabinet including an inlet channel and an outlet channel extending to an upper portion of the cabinet according to another example embodiment.

FIG. 8 is a block diagram of the cabinet of FIG. 7 but including channels having circular cross sections according to yet another example embodiment.

FIG. 9 is an isometric view of a door for a cabinet including two inlet channels, two outlet channels, and two TECs according to another example embodiment.

FIG. 10 is an enlarged isometric view of one inlet channel, one outlet channel, and one TEC of FIG. 9.

FIG. 11 is a graph including a concentration of undesirable gas and a rate of increase in the undesirable gas in a cabinet according to another example embodiment.

Corresponding reference numerals indicate corresponding parts or features throughout the several views of the drawings.

### DETAILED DESCRIPTION

Example embodiments will now be described more fully with reference to the accompanying drawings.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

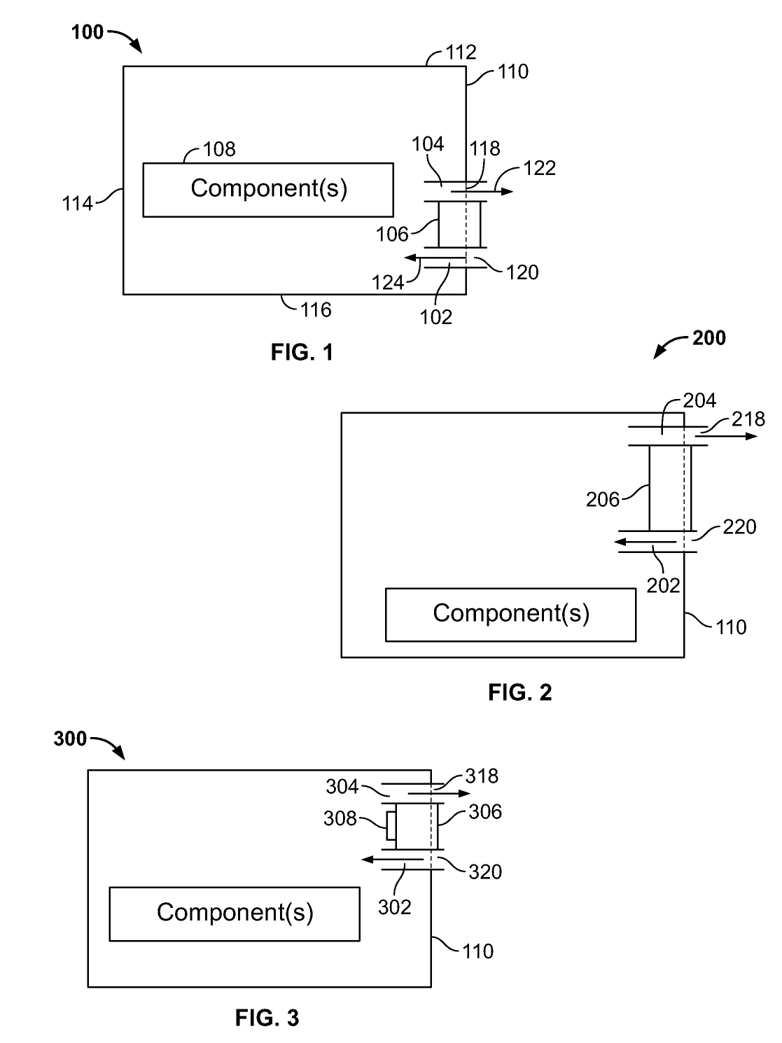

A cabinet for housing one or more components capable of releasing an undesirable gas over time according to one example embodiment of the present disclosure is illustrated in FIG. 1, and indicated generally by reference number 100. As shown in FIG. 1, the cabinet 100 includes an inlet channel 102 for conveying air from an exterior side of the cabinet 100 to an interior side of the cabinet 100, an outlet channel 104 for conveying air and undesirable gas from the interior side of the cabinet 100 to the exterior side of the cabinet 100, and a TEM 106 thermally coupled to the inlet channel 102 and/or the outlet channel 104 for promoting a temperature differential between air in the inlet channel 102 and air in the outlet channel 104. The temperature differential promotes a flow of air from the interior side of the cabinet 100 through the outlet channel 104 to the exterior side of the cabinet 100 to thereby remove the undesirable gas from the cabinet 100.

By promoting this temperature differential, air in the inlet channel 102 may become cooler and/or air in the outlet channel 104 may become warmer. As a result, air within the inlet channel 102 may become cooler than its surrounding ambient air (e.g., within the cabinet 100, etc.) and/or air within the outlet channel 104 may become warmer than its surrounding ambient air (e.g., within, adjacent to, etc. the cabinet 100). Because the density of air is inversely related to air temperature, cooler air within the inlet channel 102 (relative to its surrounding ambient air) flows to a lower portion of the cabinet 100 while warmer air within the outlet channel 104 (relative to its surrounding ambient air) exhausts from the cabinet 100.

As air in the lower portion of the cabinet 100 becomes warmer (and less dense) and/or as cooler, more dense, air enters the cabinet 100 via the inlet channel 102, existing air in the lower portion of the cabinet 100 rises. At least some of this air may enter the outlet channel 104 and exhaust from the cabinet 100 (represented by arrow 122) as explained above. Thus, this temperature differential between air in the inlet channel 102 and air in the outlet channel 104 may promote a flow of air into (represented by arrow 124) and out of the cabinet 100 thereby inducing, enhancing, etc. air movement within the cabinet 100.

Because the TEM 106 promotes the temperature differential between the inlet channel 102 and the outlet channel 104, air flow in the cabinet 100 (including the channels 102, 104) may be accomplished without the need of a fan and/or other power consuming and sometimes unreliable components. Therefore, and as shown in FIG. 1, the cabinet 100 does not include a fan to promote airflow in the cabinet 100. Alternatively, one or more fans may be positioned in the cabinet 100 (including within the one or both channels 102, 104) to further promote air flow in the cabinet 100.

The above example of air flow in the cabinet 100 is sometimes referred to as the stack effect, the chimney effect, etc. The stack effect may be enhanced (e.g., more air flow entering and existing the cabinet 100) by creating a greater temperature differential in the inlet and the outlet channels, increasing the volume of the channels (e.g., increasing the length), utilizing one or more fans (as explained above), etc.

Additionally, the undesirable gas released by components 108 in the cabinet 100 may be forced to flow with the circulating air path and exhaust from the cabinet 100 through the outlet channel 104 as explained above. Further, because the undesirable gas may be less dense than the surrounding air in the cabinet 100 and therefore more buoyant, the undesirable gas may rise to the upper portion of the cabinet 100 as explained above. As such, the concentration of undesirable gas in the cabinet 100 may remain substantially at or below a suitable level (e.g., at or below about four percent, one percent, etc.).

The temperature differential between air in the inlet channel 102 and air in the outlet channel 104 may be promoted by cooling air in the inlet channel 102 and/or warming air in the outlet channel 104. This may be accomplished by applying current to the TEM 106 that in turn moves heat from one side of the TEM 106 to the other side. As a result, one side of the TEM 106 gets cooler (e.g., a cold side, etc.) and/or the other side gets warmer (e.g., a hot side, etc.). Since the TEM 106 is thermally coupled to the inlet channel 102 and/or the outlet channel 104, air temperature in the outlet channel 104 may raise, remain substantially constant, etc. from heat transferred from the hot side of the TEM 106 and/or air temperature in the inlet channel 102 may lower, remain substantially constant, etc. from exposure (e.g., directly or indirectly) to the cold side of the TEM 106.

The TEM 106 may be thermally coupled to the inlet channel 102 and/or the outlet channel 104 in any suitable manner so long as air within one or both channels is exposed to the TEM 106. For example, the TEM 106 may be directly coupled to one or both channels, the TEM 106 may be coupled to one or both channels via an intervening thermally conductive substance (e.g., air, conductive material, etc.), etc. In the particular example of FIG. 1, the TEM 106 is positioned between the channels 102, 104 such that the TEM is directly coupled to each channel 102, 104.

In some embodiments, the TEM 106 may be positioned (e.g., entirely, at least partially, etc.) within one or both channels, positioned partially between the channels, etc. For example, and as further explained below, the TEM 106 may include one or more heat sinks extending into the inlet channel 102 and/or the outlet channel 104.

In some examples, a temperature differential between air in the inlet channel 102 and air in the outlet channel 104 may not exist. In such cases, the TEM 106 may induce a temperature differential to encourage a flow of air as explained above. In other examples, a temperature differential between air in the inlet channel 102 and air in the outlet channel 104 may exist. In this case, the TEM 106 may enhance the temperature differential to increase a flow of air as explained above.

As shown in FIG. 1, the cabinet 100 includes multiple walls 110, 112, 114, 116 defining a perimeter of the cabinet. In the example of FIG. 1, the walls 110, 114 represent two side walls of the cabinet 100, the wall 112 represents a top wall of the cabinet 100, and the wall 116 represents a bottom wall of the cabinet 100.

The wall 110 defines an inlet port 120 for coupling to the inlet channel 102 and an outlet port 118 for coupling to the outlet channel 104. As shown in FIG. 1, the inlet port 120 is positioned adjacent the outlet port 118. As such, air may flow through each channel and each port to either exit and/or enter the cabinet 100.

By having the inlet port 120 adjacent the outlet port 118, an undesirable flow of air caused by a temperature differential between inside the cabinet 100 and outside of the cabinet 100 may be reduced. For example, if the inlet port 120 is positioned near a lower portion of the cabinet 100 and the outlet port 118 is positioned near an upper portion of the cabinet 100, air may flow in the outlet port 118 and out the inlet port 120 if the air temperature outside the cabinet 100 is less than the air temperature inside the cabinet 100. This may reduce the amount of undesirable gas exhausted from the cabinet 100 because while the undesirable gas may be forced upwards (e.g., due to the buoyancy of the undesirable gas as explained above), the air flow path is forcing air downwards in the cabinet 100. Thus, air within the cabinet 100 may become substantially stagnant.

Alternatively, the inlet port 120 may not be positioned adjacent the outlet port 118. For example, the inlet port 120 may be positioned near the lower portion of the cabinet and outlet port 118 may be positioned near the upper portion of the cabinet. In such examples, if the air temperature outside the cabinet 100 is more than the air temperature inside the cabinet 100, air may flow in the inlet port 120 and out the outlet port 118 and thus work with the upward flow of the undesirable gas as explained above.

As shown in FIG. 1, the side walls 110, 114 each include an upper portion and an opposing lower portion. In the example of FIG. 1, the inlet port 120 and the outlet port 118 are positioned on the lower portion of the sidewall 110. Alternatively, and as further explained below, the inlet and/or outlet ports may be positioned in another suitable location including, for example, adjacent the upper portion of the cabinet 100, etc.

The components may include any suitable component(s) capable of releasing an undesirable gas over time. For example, the components 108 may include one or more rechargeable batteries capable of releasing hydrogen gas.

FIG. 2 illustrates another example cabinet 200 substantially similar to the cabinet 100 of FIG. 1. The cabinet 200 of FIG. 2, however, includes an inlet channel 202 and an outlet channel 204 coupled to an inlet port 220 and an outlet port 218, respectively, that are not positioned adjacent each other. For example, although the inlet channel 202 and/or the outlet channel 204 are thermally coupled to a TEM 206, the inlet channel 202 and the inlet port 220 are positioned adjacent a middle portion of the sidewall 110 while the outlet channel 204 and the outlet port 218 are positioned adjacent an upper portion of the sidewall 110.

In the some embodiments, a TEM may be controlled by a control circuit. For example, FIG. 3 illustrates a cabinet 300 substantially similar to the cabinet 100 of FIG. 1. The cabinet 300, however, includes a TEM 306 having a control circuit 308 for selectively energizing the TEM 306. The TEM 306 may be energized from a DC bus (not shown) in the cabinet 300.

In some embodiments, the control circuit 308 may continuously energize the TEM 306 so that a temperature differential is continuously present. Alternatively, the control circuit 308 may periodically energize the TEM 306 to reduce operating costs of the TEM 306, etc. The TEM 306 may be, for example, periodically energized based on one or more of a defined period of time, a defined level of undesirable gas, a defined temperature, a triggering event, etc. For example, the TEM 306 may be energized when batteries in the cabinet 300 are recharging and for a defined period of time after the batteries have recharged, only when batteries in the cabinet 300 are recharging, etc.

The control circuit 308 may also detect whether the TEM 306 is malfunctioning and then activate one or more alarms internal and/or external the cabinet 300 to warn individuals of the malfunctioning TEM 306. As such, the malfunctioning TEM 306 may be replaced, repaired, etc. before the concentration of undesirable gas in the cabinet 300 reaches, exceeds, etc. a defined level. The alarms may be placed in the cabinet 300, attached to the exterior side of the cabinet 300, remote from the cabinet 300, etc.

Additionally, the cabinet 300 includes an inlet channel 302 and an outlet channel 304 thermally coupled to the TEM 306. The inlet channel 302 is coupled to an inlet port 320 and the outlet channel 304 is coupled to an outlet port 318. As shown in FIG. 3, the inlet port 320, the outlet port 318, and the TEM 306 are positioned on the upper portion of the sidewall 110. Accordingly, the inlet port 320, the outlet port 318, and the TEM 306 are positioned adjacent a top end of the cabinet 300.

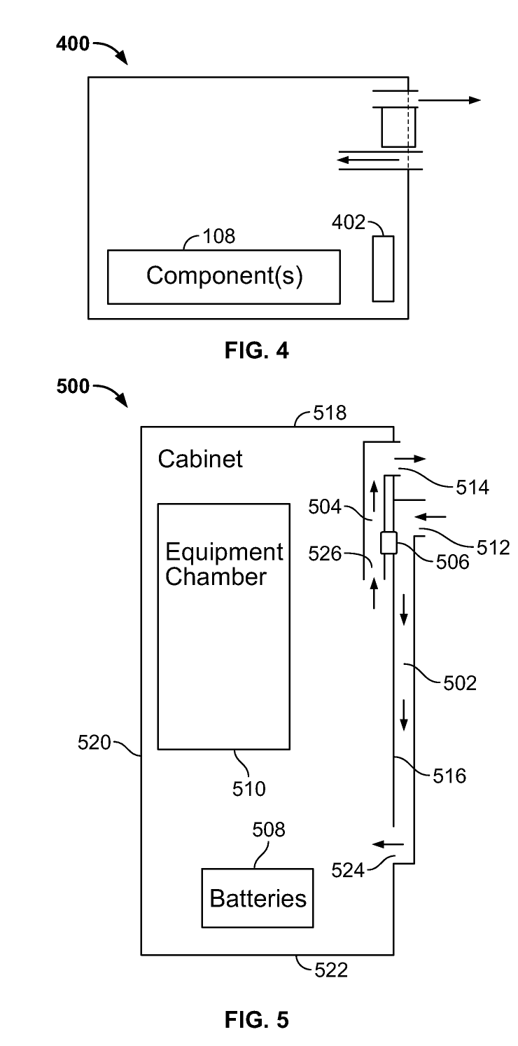

In the some examples, a temperature control device may be employed to maintain a temperature within a cabinet. For example, FIG. 4 illustrates a cabinet 400 similar to the cabinet 300 of FIG. 3. The cabinet 400, however, includes a temperature control device 402 adjacent the components 108. As such, the temperature about the components 108 (e.g., rechargeable batteries, etc.) may be maintained at or about a defined value.

Additionally and alternatively, the temperature control device 402 and/or other temperature control devices may be positioned in other portions of the cabinet 400 to maintain a temperature about other components (e.g., heat sensitive components such as converters, rectifiers, control circuits, batteries, etc.) that may be present in the cabinet 400. The temperature control devices may include, for example, fans, heat dissipating components, and/or any other suitable device for maintaining a temperature within the cabinet 400.

FIG. 5 illustrates another example cabinet 500 including an inlet channel 502, an outlet channel 504, and a TEM 506 thermally coupled to the inlet channel 502 and the outlet channel 504. The TEM 506 promotes a temperature differential between air in the inlet channel 502 and air in the outlet channel 504 to induce, enhance, etc. a flow of air from an interior side of the cabinet 500 through the outlet channel 504 to an exterior side of the cabinet 500 as explained above. As shown in FIG. 5, portions of the TEM 506 are positioned within the channels 502, 504 such that the TEM 506 is directly coupled to the channels.

As shown in FIG. 5, the inlet channel 502 and the outlet channel 504 are coupled to an inlet port 512 and an outlet port 514, respectively. In the example of FIG. 5, the inlet port 512 and the outlet port 514 are positioned adjacent to one another and an upper portion of the cabinet 500.

Similar to the cabinet 100 of FIG. 1, the cabinet 500 of FIG. 5 includes multiple walls (e.g., two sides walls 516, 520, a top wall 518, and a bottom wall 522) defining an interior for housing one or more batteries 508 and an equipment chamber 510 including components (e.g., converters, rectifiers, control circuits, etc.). Thus, the cabinet 500 may be considered a battery cabinet.

The batteries 508 may release (e.g., outgas, etc.) hydrogen gas when recharging. This hydrogen gas may flow upwards to the outlet channel 504 as explained above. As such, the equipment chamber 510 may be sealed to protect internal components (e.g., converters, rectifiers, control circuits, etc.) from being exposed to the hydrogen gas.

In the example of FIG. 5, the inlet channel 502 extends from an upper portion to a lower portion of the sidewall 516. At this location, the inlet channel 502 and the side wall 516 define an interior side opening 524 in fluid communication with the interior portion of the cabinet 500. By doing so, the length of the inlet channel 502 may be increased (e.g., compared to the inlet channels of FIGS. 1-4) to enhance the stack effect as explained above.

Additionally, the inlet channel 502 extends along an exterior side of the cabinet 500. In particular, the inlet channel 502 extends along an exterior side of the side wall 516. Thus, and as shown in FIG. 5, the exterior side of the side wall 516 defines a portion of the inlet channel 502. By employing this inlet channel configuration, usable space in the cabinet 500 may be increased, materials, costs, etc. may be reduced, etc.

As shown in FIG. 5, the outlet channel 504 may extend downwardly from the outlet port 514 to an upper portion of the cabinet 500 along an interior side of the cabinet 500. At this location, the outlet channel 504 defines an interior side opening 526 in fluid communication with the interior portion of the cabinet 500. In particular, the outlet channel 504 extends on an interior side of the side wall 516. Thus, and as shown in FIG. 5, the interior side opening 526 of outlet channel 504 and interior side opening 524 of the inlet channel 502 are not adjacent to each other.

By having the outlet channel 504 including its interior side opening 526 adjacent the upper portion of the cabinet 500, an increased amount of hydrogen gas may be exhausted from the cabinet 500 compared to, for example, an outlet channel and opening near a middle and/or lower portion of the cabinet 500. This is because the hydrogen gas rises to the upper portion of the cabinet 500 (as explained above) and thus the upper portion of the cabinet 500 may include a higher concentration of hydrogen gas available for exhausting compared to other portions of the cabinet 500.

Alternatively, the inlet channel 502 may extend along the interior side of the cabinet 500 and/or the outlet channel 504 may extend along the exterior side of the cabinet 500. Thus, the inlet channel 502 and the outlet channel 504 may extend on the same side (e.g., the interior side, etc.), opposite sides (e.g., as shown in FIG. 5), etc. of the cabinet 500.

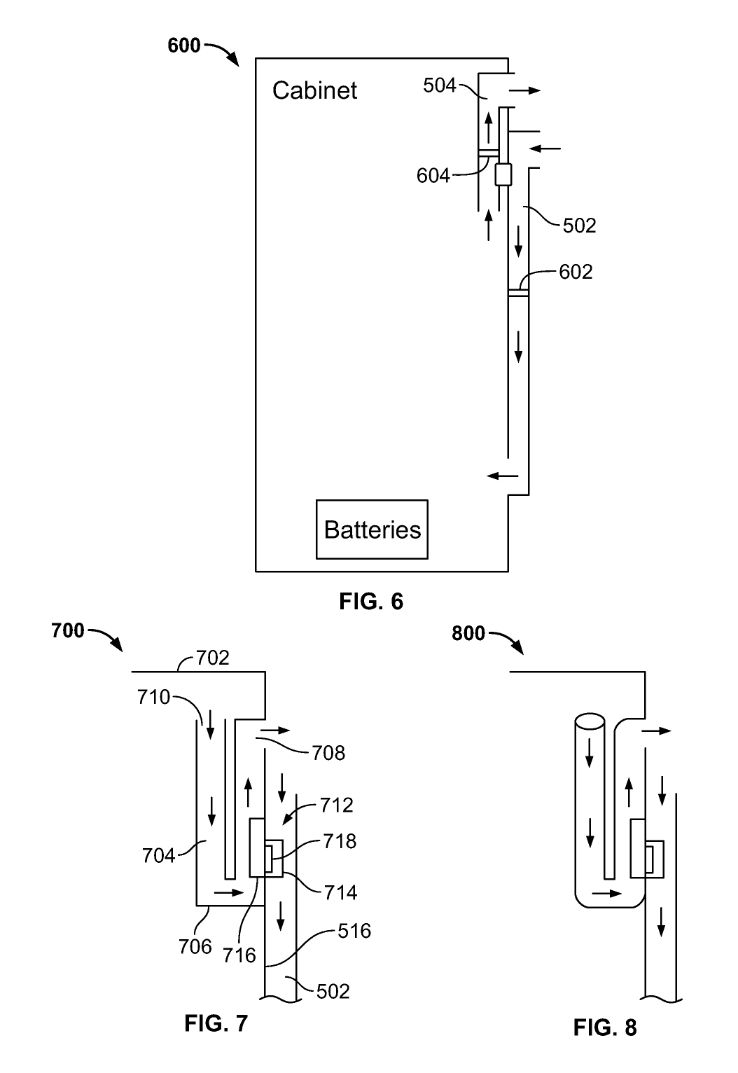

In some embodiments, one or more filters may be employed to substantially prevent undesired contaminants from entering a cabinet. For example, FIG. 6 illustrates a cabinet 600 substantially similar to the cabinet 500 of FIG. 5, but includes a filter 602 positioned in the inlet channel 502 and a filter 604 positioned in the outlet channel 504. One or both filters 602, 604 may prevent solid and/or liquid contaminants from entering the cabinet 600 via, for example, the inlet channel 502 and the outlet channel 504. The filters 602, 604 may be membrane filters such as hydrophobic filters, etc. or another suitable filter. Although FIG. 6 illustrates one filter per channel, it should be apparent that more than one filter may be employed for each channel if desired.

Alternatively and additionally, one or more filters may be positioned adjacent one or more inlet ports and/or outlet ports that are coupled to the inlet channel 502 and the outlet channel 504, respectively, as explained above. In such cases, these filters may substantially prevent contaminants from entering the cabinet 600 via the inlet channel 502 and/or the outlet channel 504.

In some examples, an outlet channel may include an interior side opening adjacent a top wall of the cabinet. For example, FIG. 7 illustrates a portion of a cabinet 700 substantially similar to the cabinet 500 of FIG. 5. The cabinet 700, however, includes an outlet channel 704 having an interior side opening 710 adjacent a top wall 702 (e.g., a ceiling) of the cabinet 700. Thus, the outlet channel 704 extends to an upper portion of the side wall 516, near the top wall 702, of the cabinet 700. As such, more hydrogen gas may be exhausted from the cabinet 700 compared to other examples (e.g., having an interior side opening near the middle and/or lower portion of a cabinet, etc.) because the upper portion of the cabinet 700 may include a higher concentration of hydrogen gas as explained above.

Additionally, and as shown in FIG. 7, the outlet channel 704 includes a deformation 706 between the interior side opening 710 and an outlet port 708. The deformation 706 may be, for example, a bend, an elbow, etc. in tubing, piping, walls, etc. which define the outlet channel 704.

In the particular example of FIG. 7, the deformation 706 includes two ninety (90) degree bends (e.g., one hundred eighty (180) degree deformation) to redirect the outlet channel 704 so that the interior side opening 710 is adjacent the top wall 702 as explained above. Alternatively, the deformation 706 may include bends of different angles (e.g., less than 180 degrees or more than 180 degrees) etc., more or less bends, etc. to redirect the outlet channel 704 so the interior side opening 710 is positioned in another desired location.

Additionally, the cabinet 700 includes a thermoelectric cooler (TEC) 712 having a module 718 and heat sinks 714, 716 thermally coupled to the channels 502, 704, respectively, to promote temperature differential between air in the inlet channel 502 and air in the outlet channel 704. Thus, and as explained above, air temperature in the outlet channel 704 may raise, remain substantially constant, etc. from heat transferred from a hot side of the TEC 712 via the heat sink 716 and air temperature in the inlet channel 502 may lower, remain substantially constant, etc. from exposure to a cold side of the TEC 712 via the heat sink 714.

In the example of FIG. 7, the module 718 and the heat sink 714 of the TEC 712 are positioned in the inlet channel 502, and the heat sink 716 of the TEC 712 is positioned in the outlet channel 704. Alternatively, the TEC 712 may include only one heat sink (e.g., the heat sink 716 thermally coupled to the channel 704, etc.) positioned in a channel, more than one heat sink positioned in each channel, etc.

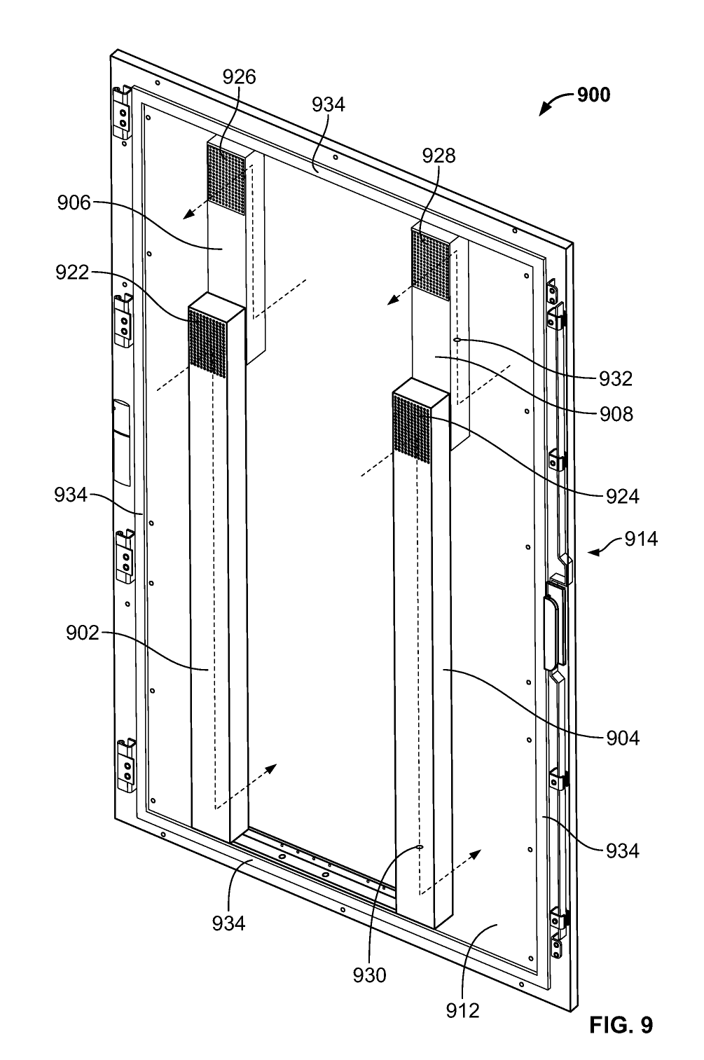

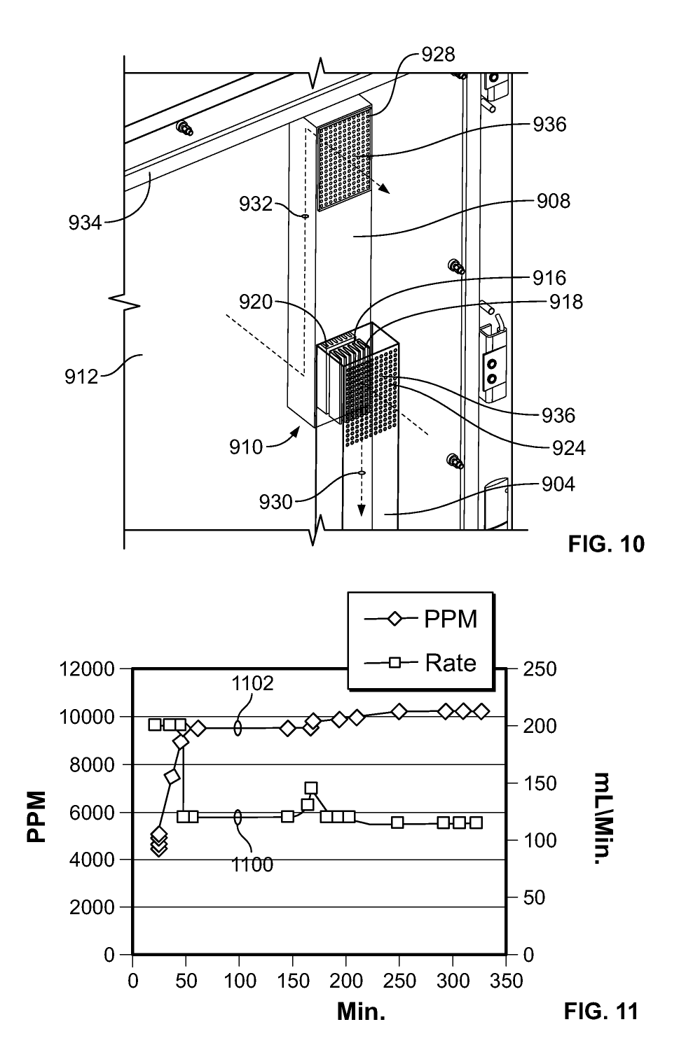

In some embodiments, a cabinet may include multiple inlet channels, outlet channels, and TEMs. For example, FIGS. 9-10 illustrate a door 900 of a cabinet for housing one or more components capable of releasing an undesirable gas over time. The cabinet includes two inlet channels 902, 904, two outlet channels 906, 908, and two TECs (one of which is shown in FIG. 10 as TEC 910). Each TEC (e.g., the TEC 910) is thermally coupled to one inlet channel (e.g., the inlet channel 904) and one outlet channel (e.g., the outlet channel 908) as explained above.

Each TEC of FIGS. 9-10 may be energized at the same time to provide additional venting of the undesirable gas. Alternatively, one TEC may serve as a primary TEC and the other TEC may be a secondary (e.g., a backup) TEC. In such cases, the primary TEC is energized and if this TEC malfunctions, etc., the secondary TEC is energized to ensure suitable venting of the undesirable gas. In other embodiments, each TEC may be energized periodically, randomly, etc. at different times.

Each TEC of FIGS. 9-10 may be controlled by its own control circuit (not shown). For example, each control circuit may selectively energize its TEC, detect whether its TEC is malfunctioning, activate alarm(s), etc. as explained above.

As shown in FIGS. 9-10, the inlet channels 902, 904, the outlet channels 906, 908, and the TECs are positioned on the door 900. For example, the inlet channels 902, 904 are positioned on an exterior side 912 of the door 900 and the outlet channels 906, 908 are positioned on an interior side 914 of the door 900. This may, for example, allow users to install, repair, replace, etc. components (e.g., the channels, the TECs, batteries, converters, rectifiers, etc.) in the cabinet with greater ease, provide more access to the components in the cabinet, etc. compared to other cabinet designs.

Each TEC of FIGS. 9-10 includes a module and heat sinks positioned in a similar manner as explained above with reference to FIG. 7. For example, and as shown in FIG. 10, the TEC 910 includes a module 916 and heat sinks 918, 920 thermally coupled to the channels 904, 908, respectively, to promote temperature differential between air in the inlet channel 904 and air in the outlet channel 908 as explained above.

As shown in FIGS. 9-10, the inlet channels 902, 904 are coupled to inlet ports 922, 924, respectively, and the outlet channels 906, 908 are coupled to outlet ports 926, 928, respectively. As such, air is able to flow through interior side openings (not shown) defined by each channel and/or the door 900, through each channel, and through each port to exit the cabinet and/or enter the cabinet as explained above. Two of these air flow paths are represented by arrows 930, 932.

A cabinet including the door 900 of FIGS. 9-10 may be a sealed cabinet. For example, the door 900 may include a gasket 934 extending along a perimeter of the interior side 914 of the door to assist in sealing the cabinet when the door 900 is shut. Additionally, the cabinet may include filters 936 positioned adjacent the inlet ports 922, 924 and the outlet ports 926, 928 to prevent undesired contaminants from entering the cabinet. The filters 936 may be a screen to protect against insect intrusion, manage the ingress of water, etc. In some embodiments, the filters 936 may be a similar type, configuration, etc. to the filters 602, 604 explained above with reference to FIG. 6.

FIG. 11 illustrates a graph plotting a concentration of an undesirable gas (e.g., hydrogen, etc.) in a cabinet (e.g., the cabinet 500, etc.) and a rate of undesirable gas released in the cabinet. The concentration of undesirable gas is shown in parts-per-million (ppm) and represented by line 1102 while the rate is shown in milliliters per minute (mL/min) and represented by line 1100. As shown in FIG. 11, the rate of undesirable gas released in the cabinet stabilizes at about 120 mL/min. During this same period, the concentration of undesirable gas stabilizes at about 1% (e.g., about 10,000 ppm). Thus, by employing the methods disclosed herein, a cabinet including channels and a TEC as explained herein may have a concentration of undesirable gas at about 1% or lower when undesirable gas is released in the cabinet.

The channels disclosed herein may be any suitable shape. For example, the inlet channels and the outlet channels may have a substantially rectangular cross section as shown in FIGS. 5-7 and 9-10. Alternatively, the inlet channels and the outlet channels may have a substantially circular cross section as shown in the cabinet 800 of FIG. 8. In some embodiments, one channel may have one cross sectional shape while another channel may have a different cross sectional shape.

Additionally, the channels may be pipes, walls, etc. Additionally, depending on thermal requirements and/or characteristics, the channels may be formed of any suitable material. For example, the channels may be formed of polyvinyl chloride (PVC), metal (e.g., sheet metal, etc.), or another suitable material. In some embodiments, one channel of a cabinet may be formed of a particular material while another channel of the cabinet may be formed of another material.

The TEMs disclosed herein may be any suitable TEM. For example, the TEMs may include a TEC as shown in FIGS. 7-10 and/or another suitable assembly including a TEM having one or more heat sinks, etc. In some embodiments, the TEC may be a solid state TEC such as Peltier device, etc. Additionally, although FIGS. 1-10 illustrate one TEM thermally coupled to one inlet channel and/or one outlet channel, it should be apparent that multiple TEMs may be thermally coupled to one inlet channel and/or one outlet channel. For example, the multiple TEMs may be thermally coupled together in parallel.

The methods disclosed herein may be employed in a wide variety of cabinets including for example, cabinets deployed indoors and/or outdoors. The cabinets may be any suitable cabinet housing components (e.g., one or more batteries as explained below) capable of releasing hydrogen gas and/or another undesirable gas.

The cabinets disclosed herein may be a sealed cabinet (e.g., an environmentally sealed cabinet). For example, the cabinets may not include cutouts (or the like) that allow a free exchange of air including contaminants to enter. If appropriate, the sealed cabinet may include gaskets, seals, potting, filters (as explained herein), etc. to protect the interior of the cabinet from contaminants (e.g., moisture, dirt, air, dust, etc.). In some examples, a sealed cabinet may reduce power required to thermally regulate an interior of the cabinet.

Further, although FIGS. 1-10 illustrates cabinets having a particular size, shape, configuration, etc., the cabinets may have any suitable size, shape, configuration, etc. without departing from the scope of the present disclosure. For example, although the figures illustrate the channels, ports, and TECs on a particular side wall or door of a cabinet, it should be apparent that some or all these components may be positioned on another suitable wall (e.g., a top wall) of the cabinet.

Additionally, a cabinet, including the cabinets disclosed herein, may include any one or more features disclosed herein (e.g., control circuits, temperature control devices, position of the TEC relative the channels, configuration of the channels, etc.) in any suitable combination without departing from the scope of the present disclosure.

By employing one or more of the features described above, a concentration of undesirable gas in a cabinet may remain substantially at or below a suitable level. Additionally, because the temperature differential is created in channels as explained above, the warmer air may be limited (at least to an extent) to within the outlet channel. This may isolate the warmer air from other components (e.g., heat sensitive components such as converters, rectifiers, control circuits, batteries, etc.) in the cabinet.

Further, because the temperature differential creates an air flow path through a cabinet as explained above, temperature in the cabinet may be maintained at or below a defined temperature (e.g., ambient environment temperature, etc.). As such, this air flow path may assist in temperature control in addition to or in place of the one or more controllable fans, vents, heat dissipating components, etc.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A battery cabinet for housing one or more rechargeable batteries capable of releasing hydrogen gas over time, the battery cabinet comprising:
an inlet channel for conveying air from an exterior side of the battery cabinet to an interior side of the battery cabinet;
an outlet channel for conveying air and hydrogen gas from the interior side of the battery cabinet to the exterior side of the battery cabinet; and
a thermoelectric module (TEM) thermally coupled to the inlet channel and/or the outlet channel for promoting a temperature differential between air in the inlet channel and air in the outlet channel, the temperature differential promoting a flow of air from the interior side of the battery cabinet through the outlet channel to the exterior side of the battery cabinet to thereby remove hydrogen gas from the battery cabinet.

2. The battery cabinet of claim 1 wherein the inlet channel is coupled to an inlet port, wherein the outlet channel is coupled to an outlet port, and wherein the input port is positioned adjacent the outlet port.

3. The battery cabinet of claim 1 further comprising multiple sidewalls each having an upper portion and an lower portion opposing the upper portion, wherein the inlet channel is coupled to an inlet port, wherein the outlet channel is coupled to an outlet port, and wherein the input port and the outlet port are positioned on the upper portion of one of the multiple sidewalls of the battery cabinet.

4. The battery cabinet of claim 3 wherein the inlet channel extends to the lower portion of said one of the multiple sidewalls of the battery cabinet.

5. The battery cabinet of claim 5 wherein the outlet channel extends to the upper portion of said one of the multiple sidewalls of the battery cabinet.

6. (canceled)

7. The battery cabinet of claim 1 wherein the TEM includes a solid state thermoelectric cooler (TEC).

8. The battery cabinet of claim 7 wherein the TEM includes a heat sink thermally coupled to at least one of the inlet channel and the outlet channel.

9. The battery cabinet of claim 7 wherein the TEM is positioned adjacent a top end of the battery cabinet.

10. The battery cabinet of claim 1 wherein the TEC is positioned at least partially between the inlet channel and the outlet channel.

11. (canceled)

12. The battery cabinet of claim 1 wherein the inlet channel is a first inlet channel, the outlet channel is a first outlet channel, and the TEM is a first TEM, the battery cabinet further comprising a second inlet channel for conveying air from the exterior side of the battery cabinet to the interior side of the battery cabinet, a second outlet channel for conveying air and hydrogen gas from the interior side of the battery cabinet to the exterior side of the battery cabinet, and a second TEM thermally coupled to the second inlet channel and/or the second outlet channel for promoting a temperature differential between air in the second inlet channel and air in the second outlet channel, the temperature differential promoting a flow of air from the interior side of the battery cabinet through the second outlet channel to the exterior side of the battery cabinet to thereby remove hydrogen gas from the battery cabinet.

13. The battery cabinet of claim 1 further comprising one or more rechargeable batteries in the battery cabinet.

14. The battery cabinet of claim 13 further comprising a temperature control device configured to maintain a temperature about the one or more rechargeable batteries at a defined value.

15. (canceled)

16. The battery cabinet of claim 1 wherein the battery cabinet does not include a fan to induce airflow in the battery cabinet.

17-18. (canceled)

19. A cabinet for housing one or more components capable of releasing an undesirable gas over time, the cabinet comprising:
an inlet channel for conveying air from an exterior side of the cabinet to an interior side of the cabinet;
an outlet channel for conveying air and undesirable gas from the interior side of the cabinet to the exterior side of the cabinet; and
a thermoelectric module (TEM) thermally coupled to the inlet channel and/or the outlet channel for promoting a temperature differential between air in the inlet channel and air in the outlet channel, the temperature differential promoting a flow of air from the interior side of the cabinet through the outlet channel to the exterior side of the cabinet to thereby remove the undesirable gas from the cabinet.

20. The cabinet of claim 19 further comprising multiple sidewalls defining a perimeter of the cabinet, each of the multiple sidewalls having an upper portion and an lower portion opposing the upper portion, wherein the inlet channel is coupled to an inlet port, wherein the outlet channel is coupled to an outlet port, and wherein the input port and the outlet port are positioned on the upper portion of one of the multiple sidewalls of the battery cabinet.

21. The cabinet of claim 19 wherein the inlet channel extends to the lower portion of said one of the multiple sidewalls of the cabinet.

22. The cabinet of claim 21 wherein the outlet channel extends to the upper portion of said one of the multiple sidewalls of the cabinet

23. The cabinet of claim 22 wherein the cabinet includes one or more components capable of releasing the undesirable gas.

24. The cabinet of claim 23 wherein the one or more components includes at least one rechargeable battery and wherein the undesirable gas includes hydrogen gas.

25. A method of promoting a flow of air from an interior side of a battery cabinet to an exterior side of the battery cabinet to thereby remove hydrogen gas from the battery cabinet, the method comprising:
promoting a temperature differential between air in an inlet channel and air in an outlet channel with a thermoelectric module (TEM) to promote a flow of air from the interior side of the battery cabinet through the outlet channel to the exterior side of the battery cabinet to thereby remove hydrogen gas from the battery cabinet.
